(19) United States
(12) Patent Application Publication
(10) Pub. No.: US 2024/0006297 A1
(43) Pub. Date: Jan. 4, 2024

(54) SILICIDE AND SILICON NITRIDE LAYERS BETWEEN A DIELECTRIC AND COPPER

(71) Applicant: Intel Corporation, Santa Clara, CA (US)

(72) Inventors: Suddhasattwa NAD, Chandler, AZ (US); Kristof DARMAWIKARTA, Chandler, AZ (US); Srinivas V. PIETAMBARAM, Chandler, AZ (US); Tarek A. IBRAHIM, Mesa, AZ (US); Rahul N. MANEPALLI, Chandler, AZ (US); Darko GRUJICIC, Chandler, AZ (US); Marcel WALL, Phoenix, AZ (US); Yi YANG, Gilbert, AZ (US)

(21) Appl. No.: 17/853,582

(22) Filed: Jun. 29, 2022

(51) Int. Cl. H01L 23/498; H01L 21/48; H01L 23/538

(52) U.S. Cl. CPC H01L 23/49894; H01L 21/4846; H01L 23/538; H01L 21/481

(57) ABSTRACT

Embodiments herein relate to systems, apparatuses, or processes for forming a silicide and a silicon nitrate layer between a copper feature and dielectric to reduce delamination of the dielectric. Embodiments allow an unroughened surface for the copper feature to reduce the insertion loss for transmission lines that go through the unroughened surface of the copper. Embodiments may include sequential interlayers between a dielectric and copper. Other embodiments may be described and/or claimed.

### FIELD

Embodiments of the present disclosure generally relate to the field of package assemblies, and in particular package assemblies that include substrates with copper traces.

### BACKGROUND

Continued reduction in end product size of mobile electronic devices such as smart phones and ultrabooks is a driving force for the development of reduced size system in package components. As speed requirements between dies on a package, for example between a compute die and a memory die, continues to increase, density of traces in a package substrate will continue to increase, and the increased signal frequency and speed of transmission on these traces will become increasingly important.

### BRIEF DESCRIPTION OF THE DRAWINGS

FIG. 1 illustrates cross section side views of a legacy substrate with a layer that includes a dielectric directly contacting roughened copper traces.

FIG. 2 illustrates cross section side views of a substrate with a layer that includes a silicide layer and a silicon nitride layer between the dielectric and unroughened copper traces, in accordance with various embodiments.

FIGS. 3A-3E illustrate stages in a manufacturing process for creating a substrate that includes a layer of copper traces on a dielectric that includes a silicide layer and a silicon nitride layer surrounding a portion of the copper traces, in accordance with various embodiments.

FIGS. 4A-4F illustrate stages in a manufacturing process for creating a substrate that includes a layer of copper traces on a dielectric that includes a silicide layer and a silicon nitride on a top surface of the copper traces, in accordance with various embodiments.

FIG. 5 illustrates a cross section side view of a copper trace that includes a silicide layer and a silicon nitride layer on only the top surface of the copper trace, in accordance with various embodiments.

FIG. 6 illustrates an example of a process for creating a substrate that includes silicide and silicon nitride layers between a dielectric and a copper feature of the substrate, in accordance with various embodiments.

FIG. 7 schematically illustrates a computing device, in accordance with various embodiments.

### DETAILED DESCRIPTION

Embodiments of the present disclosure may generally relate to systems, apparatus, and/or processes directed to increasing the speed and density of input/output (I/O) on substrates by using unroughened surfaces on the pads or traces to achieve higher signal frequency and higher speeds, and reduce insertion loss, through transmission lines that go through the surfaces. In embodiments, a silicide layer, which may be referred to as a silicide interlayer, and a silicon nitride layer may be placed between a copper trace and a dielectric on the copper trace to reduce the delamination risk of the dielectric from the copper trace. In embodiments, this allows a strong bond between the copper trace and the dielectric without having to roughen a surface of the copper trace prior to applying the dielectric. Embodiments may result in unroughened copper trace surfaces and a higher life of the substrate and packages to which the substrate is included. Embodiments may be referred to as sequential interlayers between a dielectric and copper.

In embodiments described herein, a silicide interlayer may be formed between a copper trace, or other copper feature on or in a substrate, and a silicon nitride layer around the copper trace to enhance the adhesion of the silicon nitride to the copper trace. In conjunction with the silicon nitride layer, these embodiments may provide a strong adhesion of the copper traces to a dielectric that at least partially surrounds the copper traces, without requiring roughening a surface of the copper traces. In legacy implementations, when a surface of the copper feature, including a trace, is roughened, there is a loss of the copper, which decreases the plated dimensions of the copper feature.

In embodiments, the silicide interlayer and the silicon nitride layer may be applied using a single-tool during the manufacturing process, for example a chemical vapor deposition (CVD) process that involves a physical vapor deposition (PVD) process that involves plasma assisted deposition. In embodiments, the silicide interlayer may be a copper silicide interlayer. This may be referred to as a chemical-based adhesion process.

Substrates for next generation chip-to-chip interconnect technologies require higher speed and higher density input/output (IO) routing through interconnects and substrates. For example, higher speed I/O data transfer is important in order to enable support for next generation Serializer/Deserializer (SerDes) interconnects that operate at speeds of 28 GHz or greater, that operate at high frequencies will having low signal losses.

At high frequencies, a significant majority of the signal transfer is close to the surface of the conductor, for example copper traces, an effect known as the “skin effect.” At 1 MHz signal transfer, this skin effect depth is about 66 μm while at 28 GHz it reduces to about 400 nm, and reduces to about 200 nm at 100 GHz. Hence, trace roughness and the surface of the conductor starts playing a significant role in reducing signal losses at higher frequencies.

Also, the density of I/O for an interconnect is based on a variety of factors that include via size, line/space pitch, bump pitch, via-to-pad alignment, pad-to-via alignment, and material properties that include organic-based dielectric materials. For example, legacy processes to produce an interconnect with a 110 μm bump pitch results in less than 20 IO/mm/layer, for example 49 μm diameter vias, 9/12 μm L/S, and 14 μm alignment. Very high I/O density interconnects, for example densities greater than 100 IO/mm/layer, calls for advanced patterning, alignment and via formation.

Reducing the routing pitch will facilitate I/O density scaling. For example, scaling the routing pitch down to 2/2 μm. However, 2/2 μm fine line space (FLS) fabrication using a traditional semi-additive process tool and material set is a challenge, particularity with respect to limits in high resolution exposure, reduced loss of copper from copper traces due to roughening of the copper trace surfaces used for trace-to-dielectric adhesion, seed etch and thin dielectric for improved electrical performance. For example, embodiments described herein may facilitate 2/2 μm LS fabrication by transitioning away from mechanical adhesion by roughening copper trace surfaces, and moving toward chemical adhesion in order to minimize the loss of copper trace due to roughening.

Embodiments described herein are directed to improving the adhesion of the dielectric material, which may include an organic polymer/inorganic filler composite, to an unroughened copper surface. The copper layer may be pre-treated in the form of oxide removal or an inductively coupled plasma treatment for delivering a pristine copper surface.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

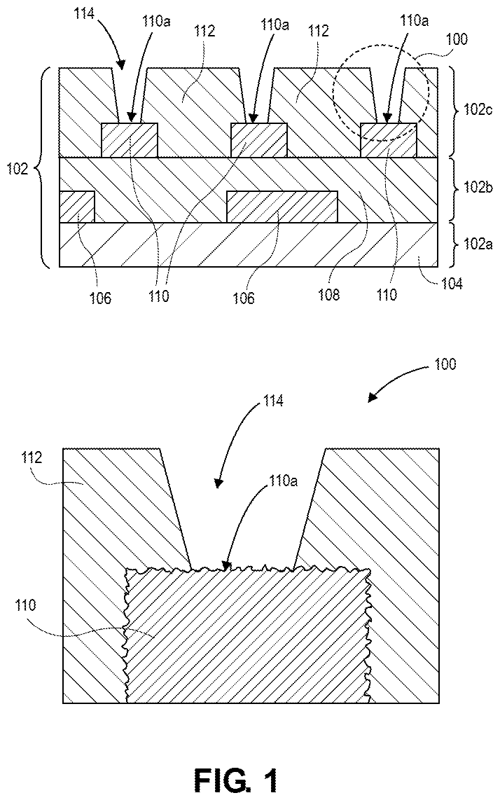

FIG. 1 illustrates cross section side views of a legacy substrate with a layer that includes a dielectric directly contacting roughened copper traces. FIG. 1 shows a portion of a legacy substrate 102 that includes a bottom layer 102a, an intermediate layer 102b, and an upper layer 102c. The bottom layer 102a may include a first dielectric 104. In implementations, the first dielectric 104 may be a portion of a glass substrate or a silicon based substrate, or a wafer.

The intermediate layer 102b may include copper features 106 that are on the bottom layer 102a. The copper features 106 in implementations may be traces. A second dielectric 108 may be on the copper features 106. Copper traces 110 may be on the second dielectric 108 and in the upper layer 102c. In implementations, the copper traces 110 may be pads onto which copper vias (not shown) or some other copper connections may be placed onto a roughened surface 110a of the copper traces 110. In implementations, a third dielectric 112 may be placed on the copper traces 110. Vias 114 may be created, for example, by drilling through the third dielectric 112 to expose the roughened surface 110a of the copper traces 110.

In implementations, to prevent delamination of the third dielectric 112 from the surfaces of the copper traces 110, the surfaces of the copper traces may be roughened, as shown in the blowup of area 100 shown in diagram 100. This may be referred to as part of a mechanical adhesion process. In implementations, the roughened surface 110a may be roughened using a wet chemical-based process for roughening the copper traces 110 before the third dielectric 112 is applied. As a result, the roughened surface 110a provides a mechanical anchor, as well as additional surface area, for the third dielectric 112 to bond with the copper trace 110.

Although in these legacy implementations the third dielectric 112 is securely anchored to the traces 110, the legacy roughening technique creates challenges. First, a distance between copper traces 110 may increase due to the impact of the etch-based roughening process. Second, the roughened surface 110a creates insertion losses for AC signal transduction, especially in high speed applications. These effects combined together result in significant performance limitations of electronic packaging substrates.

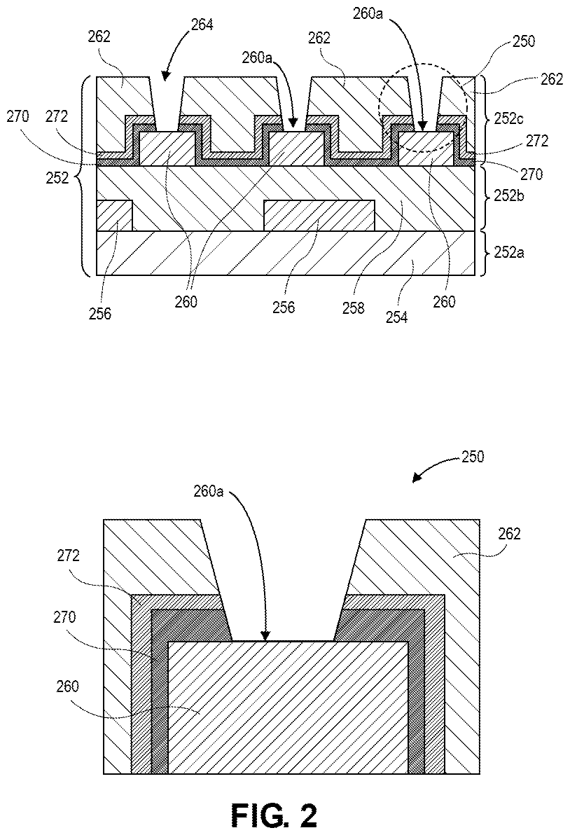

FIG. 2 illustrates cross section side views of a substrate with a layer that includes a silicide layer and a silicon nitride layer between the dielectric and unroughened copper traces, in accordance with various embodiments. FIG. 2 shows substrate 252, which may be a portion of an interconnect, that includes a bottom layer 252a, an intermediate layer 252b, and an upper layer 252c. The bottom layer 252a may include a first dielectric 254. In embodiments, the first dielectric 254 may be a portion of a wafer.

The intermediate layer 252b may include copper features 256 that are on the bottom layer 252a. The copper features 256 in embodiments may be traces. A second dielectric 258 may be on the copper features 256. Copper traces 260 may be on the second dielectric 258 and in the upper layer 252c. In implementations, the copper traces 260 may be pads onto which copper (not shown) or other electrically conductive material may be placed onto a surface 260a of the copper traces 260 that form a portion of a signal transmission line. In implementations, a third dielectric 262 may be placed on the copper traces 260. Vias 264 may be created, for example by drilling, through the third dielectric 262 to expose the surface 260a of the copper traces 260. In embodiments, the first dielectric 254, the second dielectric 258, and the third dielectric 262 may include the same materials, or may include different materials.

In embodiments, a silicide layer 270 may be placed on the surface of the second dielectric 258 after the copper traces 260 are placed on the dielectric 258. In embodiments, the silicide layer 270 may be a copper silicide, cobalt silicide, ruthenium silicide, or tungsten silicide layer. In embodiments, the silicide layer 270 may have a thickness of 2 μm or less. In embodiments, a thickness of the silicide layer 270 may be variable. In embodiments, as described further below, the silicide layer 270 may be deposited using a CVD plasma process.

In embodiments, a silicon nitride (SiNₓ) layer 272 may be deposited on the silicide layer 270, with the third dielectric 262 placed on the silicon nitride layer 272. In embodiments, the silicide layer 270 may form a chemical bond with the silicon nitride layer 272. This, in conjunction with the tight chemical bond that is formed between the silicon nitride layer 272 and the third dielectric 262, the third dielectric 262 as a result may be tightly chemically adhered to the copper trace 260. In some embodiments, the silicide layer 270 may be omitted, and only a silicon nitride layer 272 may be placed between the third dielectric 262 and the copper trace 260.

In embodiments, the surface 260a of the copper trace 260 may be unroughened, as shown in the blowup of the area 250. In embodiments, the surface 260a may be less than a 100 nm arithmetic mean roughness (Ra) in roughness, while roughened layers typically are greater than 100 nm Ra in roughness. In embodiments, the surface 260a of the copper trace 260 does not require roughening.

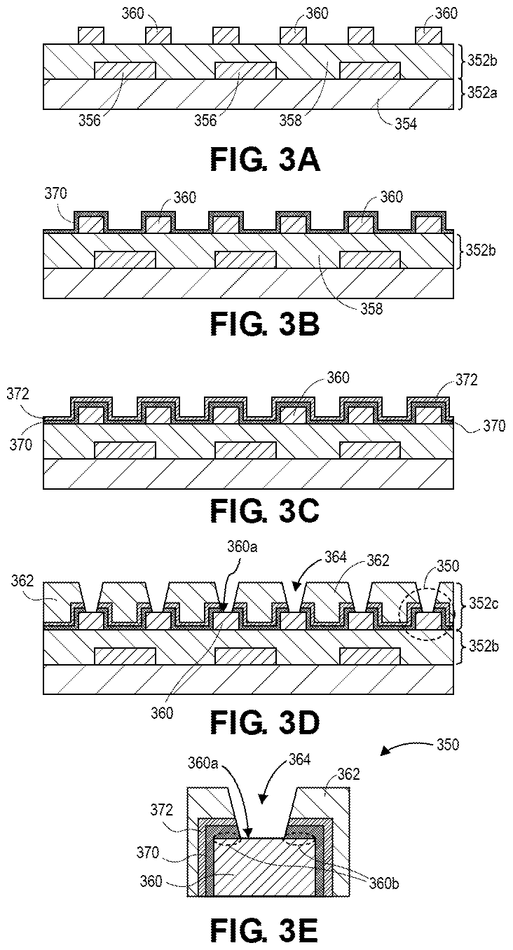

FIGS. 3A-3E illustrate stages in a manufacturing process for creating a substrate that includes a layer of copper traces on a dielectric that includes a silicide layer and a silicon nitride layer surrounding a portion of the copper traces, in accordance with various embodiments. In embodiments, the stages may be performed as part of a semi-additive process (SAP) flow. FIG. 3A shows a cross section side view of a stage in the manufacturing process that includes a first layer 352a and a second layer 352b on the first layer 352a. The first layer 352a may include a first dielectric 354.

In embodiments, copper traces 356 may be placed on the first layer 352a. In embodiments, the copper traces 356 may be electrical routing features, or may be some other copper feature. In embodiments, the copper traces 360 may be copper pads. A second dielectric 358 may be placed on the first layer 352a and surround the copper traces 356. In embodiments, the second dielectric 358 may be similar to the first dielectric 354. In embodiments, copper traces 360 may be placed on the second dielectric 358 of layer 352b. The copper traces 360 may be formed using standard techniques, for example electroplating, physical vapor deposition (PVD), chemical vapor deposition (CVD), or atomic layer deposition (ALD).

FIG. 3B shows a cross section side view of a stage in the manufacturing process where a silicide layer 370 is applied to the top of the second layer 352b, and on the copper traces 360. In embodiments, the silicide may be a copper silicide. In embodiments, the silicide layer 370 forms an adhesion layer and may be applied using inductively coupled plasma CVD, amongst other techniques, to provide a conformal layer on the copper traces 360. In embodiments, a CVD process may be used for deposition.

FIG. 3C shows a cross section side view of a stage in the manufacturing process where a silicon nitride layer 372 is deposited over the silicide layer 370. In embodiments, a CVD process or a physical vapor deposition (PVD) process may be used for deposition. In embodiments, the silicide layer 370 will enhance the bonding between the silicon nitride layer 372 and the copper trace 360.

FIG. 3D shows a cross section side view of a stage in the manufacturing process where a third dielectric 362 is placed on the silicon nitride layer 372 above the second layer 352b. The third dielectric 362, the silicon nitride layer 372, the silicide layer 370, and the copper traces 360 may form a third layer 352c of the substrate.

Subsequent to the placement of the third dielectric 362, vias 364 may be formed through the third dielectric 362 to expose a surface 360a of copper trace 360. In embodiments, the vias 364 may be formed using a mechanical or laser drill and reach the surface 360a of the copper trace 360. In embodiments, the surface 360a may be ablated or abraded in preparation for forming a direct copper-to-copper interconnect when copper is placed into the via 364. Note that in the embodiments the surface 360a has not been roughened. Area 350 is shown as a blow up in FIG. 3E.

FIG. 3E shows a blown up cross section side view of area 350 on FIG. 3D, that includes via 364, copper trace 360, silicide 370, silicon nitride 372 and third dielectric 362. Note the areas 360b of the surface of the copper trace 360 that surround the surface 360a, where the silicide layer 370 and the silicon nitride layer 372 are between the copper trace 360 and the third dielectric 362. This facilitates adhesion of the third dielectric 362 with the copper trace 360.

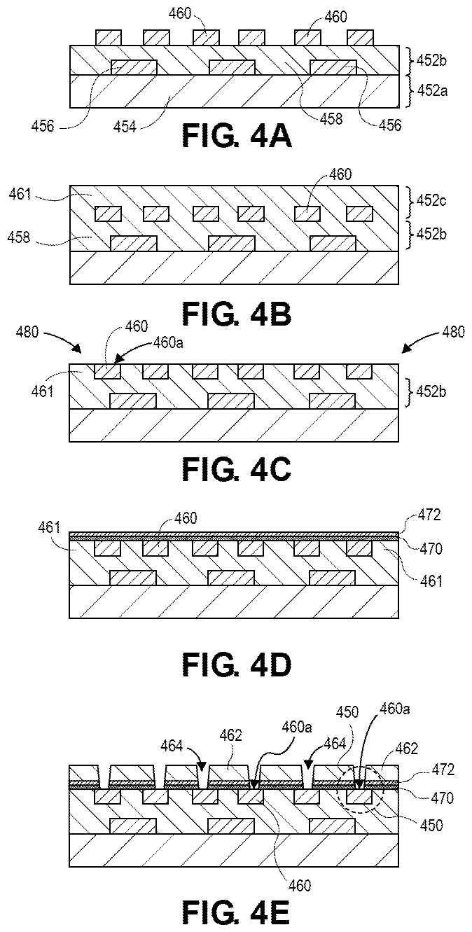

FIGS. 4A-4F illustrate stages in a manufacturing process for creating a substrate that includes a layer of copper traces on a dielectric that includes a silicide layer and a silicon nitride on a top surface of the copper traces, in accordance with various embodiments. In embodiments, the stages may be performed as part of a SAP flow. FIG. 4A shows a cross section side view of a stage in the manufacturing process that includes a first layer 452a and a second layer 452b on the first layer 452a. The first layer 452a may include a first dielectric 454.

In embodiments, copper traces 456 may be placed on the first layer 452a. In embodiments, the copper traces 456 may be electrical routing features, or may be some other copper feature. A second dielectric 458 may be placed on the first layer 452a and surround the copper traces 456. In embodiments, the second dielectric 458 may be the same or may be different than the first dielectric 454. In embodiments, copper traces 460 may be placed on the second dielectric 458 of layer 452b. In embodiments, the copper traces 460 may be copper pads. The copper traces 460 may be formed using standard techniques.

FIG. 4B shows a cross section side view of a stage in the manufacturing process where a third dielectric 461 is placed on the second dielectric 458, at around the copper traces 460 to form a layer 452c. In embodiments, the first dielectric 454, the second dielectric 458, and the third dielectric 461 may include similar materials.

FIG. 4C shows a cross section side view of a stage in the manufacturing process where a planarization process 480 occurs to expose a surface 460a of the copper trace 460. In embodiments, the planarization may be accomplished using chemical mechanical polishing (CMP).

FIG. 4D shows a cross section side view of a stage in the manufacturing process where a silicide layer 470, which may be similar to silicide layer 370 of FIG. 3C, is applied to the surface of the third dielectric 461 and the copper traces 460. In addition, a silicon nitride layer 472, which may be similar to silicon nitride layer 372 of FIG. 3C, may be applied to the silicide layer 470.

FIG. 4E shows a stage in the manufacturing process where a fourth dielectric 462 is placed on the silicon nitride layer 472. Subsequently, in embodiments, vias 464 are opened through the fourth dielectric 462, through the silicon nitride layer 472 and through the silicide layer 470 to expose the surface 460a of the copper trace 460.

FIG. 4F shows a blown up cross section side view of area 450 of FIG. 4E that includes via 464, copper trace 460, silicide 470, silicon nitride layer 472, and fourth dielectric 462. Note the areas 460b of the surface of the copper trace 460 that surround the surface 460a, where the silicide layer 470 and the silicon nitride layer 472 are between the copper trace 460 and the fourth dielectric 462 to facilitate adhesion of the fourth dielectric 462 with the copper trace 460.

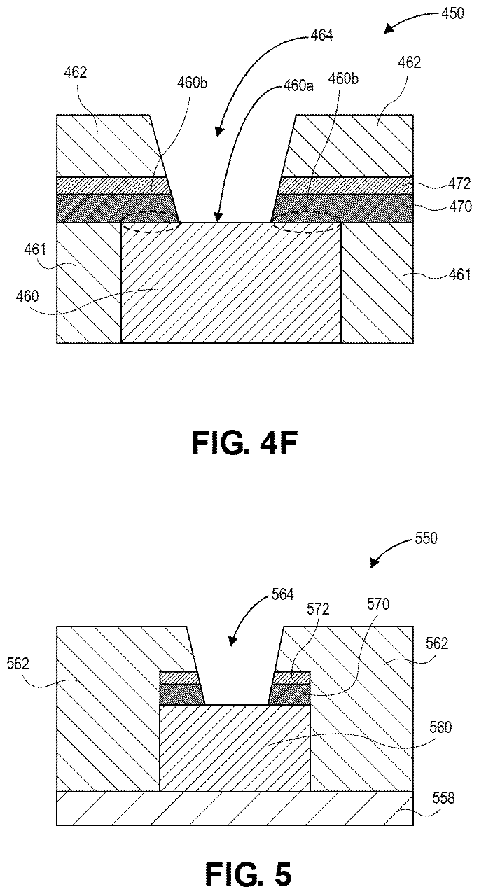

FIG. 5 illustrates a cross section side view of a copper trace that includes a silicide layer and a silicon nitride layer on only the top surface of the copper trace, in accordance with various embodiments. Diagram 550, which may be similar to area 450 of FIG. 4F, shows an alternate embodiment where the silicide layer 570, which may be similar to silicide layer 470 FIG. 4F, and the silicon nitride layer 572, which may be similar to silicon nitride layer 472 of FIG. 4F, are only at a top of the copper trace 560 and surrounding the via 564. Thus, the dielectric 562, which may be similar to the fourth dielectric 462 of FIG. 4F, is adhered to the copper trace 560 by the silicide layer 570 and the silicon nitride layer 572.

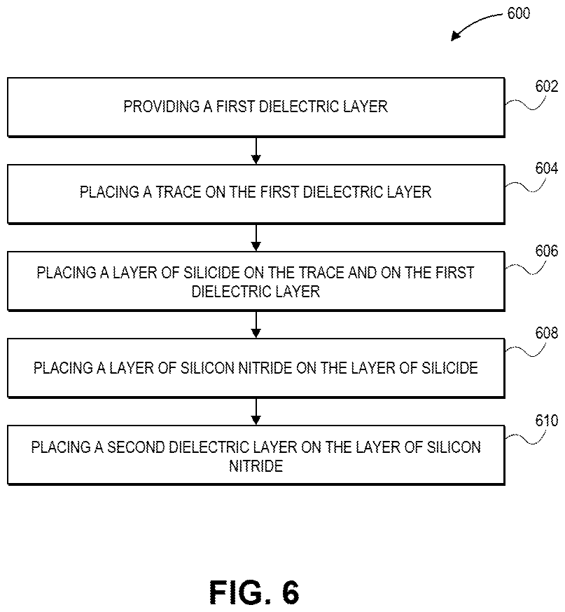

FIG. 6 illustrates an example of a process for creating a substrate that includes silicide and silicon nitride layers between a dielectric and a copper feature of the substrate, in accordance with various embodiments. Process 600 may be implemented using the techniques, systems, apparatus, and processes described herein, and in particular with respect to FIGS. 1-5.

At block 602, the process may include providing a first dielectric layer. In embodiments, the first dielectric layer may be similar to second dielectric 258 within intermediate layer 252b of FIG. 2, or may be similar to second dielectric 358 within second layer 352b of FIG. 3A, or may be similar to second dielectric 458 within layer 452b of FIG. 4A.

At block 604, the process may further include placing a trace on the first dielectric layer. In embodiments, the trace may be similar to copper trace 260 of FIG. 2, copper trace 360 of FIG. 3A, copper trace 460 of FIG. 4A, or copper trace 560 of FIG. 5.

At block 606, the process may further include placing a layer of silicide on the trace and on the first dielectric layer. In embodiments, the layer of silicide may be similar to the silicide layer 270 of FIG. 2, silicide layer 370 of FIG. 3B, silicide layer 470 of FIG. 4D, or silicide layer 570 FIG. 5.

At block 608, the process may further include placing a layer of silicon nitride on the layer of silicide. In embodiments, the layer of silicon nitride may be similar to silicon nitride layer 272 of FIG. 2, silicon nitride layer 372 of FIG. 3C, silicon nitride layer 472 of FIG. 4D, or silicon nitride layer 572 of FIG. 5.

At block 610, the process may further include placing a second dielectric layer on the layer of silicon nitride. In embodiments, the second dielectric layer may be similar to third dielectric 362 within layer 352c of FIG. 3D.

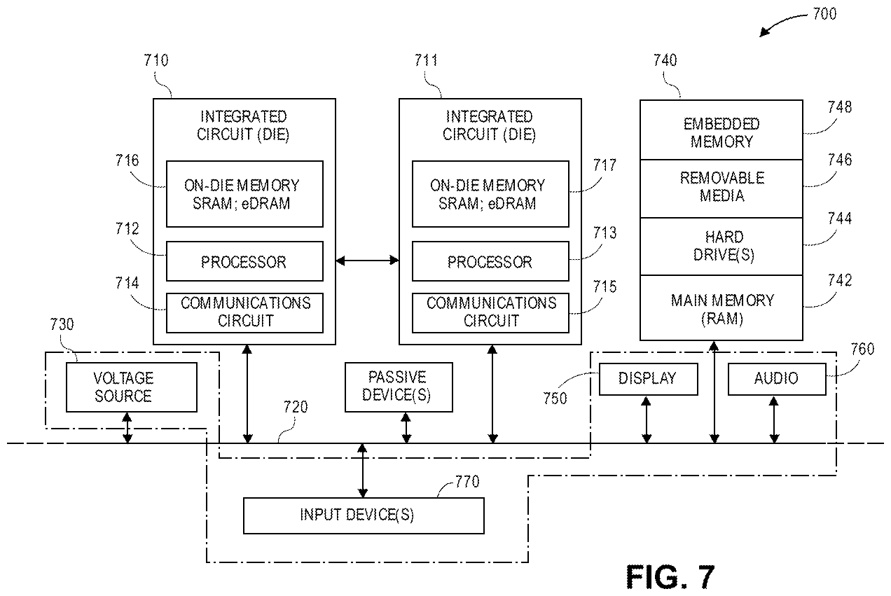

FIG. 7 is a schematic of a computer system 700, in accordance with an embodiment of the present invention. The computer system 700 (also referred to as the electronic system 700) as depicted can embody silicide and silicon nitride layers between a dielectric and copper, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, silicide and silicon nitride layers between a dielectric and copper, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having silicide and silicon nitride layers between a dielectric and copper, according to any of the several disclosed embodiments and their equivalents, an electronic system, a computer system, one or more methods of fabricating an integrated circuit, and one or more methods of fabricating an electronic assembly that includes a package substrate having silicide and silicon nitride layers between a dielectric and copper, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having silicide and silicon nitride layers between a dielectric and copper embodiments and their equivalents. A foundation substrate may be included, as represented by the dashed line of FIG. 7. Passive devices may also be included, as is also depicted in FIG. 7.

### Examples

The following paragraphs describe examples of various embodiments.
Example 1 is a substrate comprising: a first dielectric layer; a feature that includes copper on the first dielectric layer; a layer of silicide on at least part of the feature that includes copper; a layer of silicon nitride on the layer of silicide; and a second dielectric layer on the layer of silicon nitride.
Example 2 includes the substrate of example 1, or of any other example or embodiment herein, wherein the feature that includes copper is a selected one or more of: a pad or a trace.
Example 3 includes the substrate of example 1, or of any other example or embodiment herein, wherein the layer of silicide includes copper.
Example 4 includes the substrate of example 1, or of any other example or embodiment herein, wherein a thickness of the layer of silicide is less than 1 μm.
Example 5 includes the substrate of example 1, or of any other example or embodiment herein, wherein a thickness of the layer of silicon nitride is less than 1 μm.
Example 6 includes the substrate of example 1, or of any other example or embodiment herein, wherein the at least part of the copper feature includes a portion of a top surface of the copper feature opposite the first dielectric layer.
Example 7 includes the substrate of example 1, or of any other example or embodiment herein, wherein the second dielectric layer is a top layer of the substrate.
Example 8 includes the substrate of example 1, or of any other example or embodiment herein, wherein the layer of silicon nitride does not come into direct physical contact with the feature that includes copper.
Example 9 includes the substrate of example 1, or of any other example or embodiment herein, wherein a portion of the layer of silicide and a portion of the layer of silicon nitride are on a portion of the first dielectric layer.
Example 10 includes the substrate of example 1, or of any other example or embodiment herein, wherein the feature that includes copper is a first feature; and further comprising: a second feature that includes copper, wherein the second feature that includes copper is on the first dielectric layer; wherein the layer of silicide is on at least part of the second feature that includes copper; and wherein the layer of silicon nitride is on the layer of silicide that is on at least part of the second feature that includes copper.
Example 11 includes the substrate of example 10, or of any other example or embodiment herein, wherein the first feature that includes copper and the second feature that includes copper have a pitch of less than 50 μm.
Example 12 includes the substrate of example 1, or of any other example or embodiment herein, wherein the first feature that includes copper is a trace; and further comprising a metal that includes copper on the trace, wherein the trace and the metal that includes copper on the trace are directly electrically coupled.
Example 13 includes the substrate of example 12, or of any other example or embodiment herein, wherein the metal that includes copper is a portion of a metal via.
Example 14 includes the substrate of example 1, or of any other example or embodiment herein, wherein a smoothness of the surface of the feature has a roughness of less than 100 nm Ra.
Example 15 includes the substrate of example 1, or of any other example or embodiment herein, wherein the layer of silicide and the layer of silicon nitride adhere the second dielectric layer to the feature that includes copper.
Example 16 is a package comprising: a die; and a substrate electrically coupled with the die, the substrate including: a first dielectric layer; a trace that includes copper on the first dielectric layer; a layer of silicide on at least part of the trace; a layer of silicon nitride on the layer of silicide; and a second dielectric layer on the layer of silicon nitride, wherein the layer of silicide and the layer of silicon nitride are between a portion of the second dielectric layer and the at least part of the trace.
Example 17 includes the package of example 16, or of any other example or embodiment herein, wherein the die is electrically coupled with the trace.
Example 18 includes the package of example 17, or of any other example or embodiment herein, further comprising a via that includes copper that is directly electrically coupled with the trace, wherein the via is adjacent to the second dielectric layer and the via is electrically coupled with the die.
Example 19 includes the package of example 18, or of any other example or embodiment herein, wherein the via is adjacent to the layer of silicide and adjacent to the layer of silicon nitride.
Example 20 includes the package of example 16, or of any other example or embodiment herein, wherein the substrate is a portion of a serializer/deserializer device.
Example 21 includes the package of example 16, or of any other example or embodiment herein, wherein the first dielectric layer and the second dielectric layer are different dielectric compounds.
Example 22 is a method comprising: providing a first dielectric layer; placing a trace on the first dielectric layer; placing a layer of silicide on the trace and on the first dielectric layer; placing a layer of silicon nitride on the layer of silicide; and placing a second dielectric layer on the layer of silicon nitride.
Example 23 includes the method of example 22, or of any other example or embodiment herein, wherein a thickness of the layer of silicide is less than 1 μm.
Example 24 includes the method of example 22, or of any other example or embodiment herein, wherein placing the layer of silicide further includes placing the layer of silicide using a selected one of: chemical vapor deposition (CVD) process or a physical vapor deposition (PVD) process.
Example 25 includes the method of example 22, or of any other example or embodiment herein, wherein placing the layer of silicon nitride further includes placing the layer of silicon nitride using a selected one of: a CVD process or a PVD process.
Example 26 is a substrate comprising: a first dielectric layer; a feature on the first dielectric layer, the feature including copper; a first layer on at least part of the feature, the first layer comprising silicon and at least one of copper, cobalt, ruthenium, or tungsten; a second layer on the first layer, the second layer comprising silicon and nitrogen; and a second dielectric layer on the second layer.
Example 27 includes the substrate of example 26, or of any other example or embodiment herein, wherein the feature is a selected one or more of: a pad or a trace.
Example 28 includes the substrate of example 26, or of any other example or embodiment herein, wherein the first layer comprises a silicide.
Example 29 includes the substrate of example 26, or of any other example or embodiment herein, wherein a thickness of the first layer is less than 1 μm.
Example 30 includes the substrate of example 26, or of any other example or embodiment herein, wherein a thickness of the second layer is less than 1 μm.
Example 31 includes the substrate of example 26, or of any other example or embodiment herein, wherein the at least part of the copper feature includes a portion of a top surface of the copper feature opposite the first dielectric layer.
Example 32 includes the substrate of example 26, or of any other example or embodiment herein, wherein the second dielectric layer is a build up layer.
Example 33 includes the substrate of example 26, or of any other example or embodiment herein, wherein the second layer does not come into direct physical contact with the feature.
Example 34 includes the substrate of example 26, or of any other example or embodiment herein, wherein a portion of the first layer and a portion of the second layer of silicon nitride are on a portion of the first dielectric layer.
Example 35 includes the substrate of example 26, or of any other example or embodiment herein, wherein the feature is a first feature; and further comprising: a second feature, wherein the second feature includes copper and wherein the second feature is on the first dielectric layer; wherein the first layer is on at least part of the second feature; and wherein the second layer is on the first layer that is on at least part of the second feature that includes copper.
Example 36 includes the substrate of example 35, or of any other example or embodiment herein, wherein a distance between the first feature and the second feature is less than 50 μm.
Example 37 includes the substrate of example 26, or of any other example or embodiment herein, wherein the first feature is a trace; and further comprising a via electrically coupled to the trace.
Example 38 includes the substrate of example 26, or of any other example or embodiment herein, wherein a smoothness of the surface of the feature has a roughness of less than 100 nm Ra.
Example 39 includes the substrate of example 26, or of any other example or embodiment herein, wherein the first layer and the second layer adhere the second dielectric layer to the feature.
Example 40 is a package comprising: a die; and a substrate electrically coupled with the die, the substrate including: a first dielectric layer; a trace on the first dielectric layer, the trace including copper; a first layer on at least part of the trace, the first layer comprising silicon and at least one of copper, cobalt, ruthenium, or tungsten; a second layer on the first layer, the second layer comprising silicon and nitrogen; and a second dielectric layer on the second layer, wherein the first layer and the second layer are between a portion of the second dielectric layer and the at least part of the trace.
Example 41 includes the package of example 40, or of any other example or embodiment herein, wherein the die is electrically coupled with the trace.
Example 42 includes the package of example 41, or of any other example or embodiment herein, further comprising a via that is directly electrically coupled with the trace, wherein the via includes copper and wherein the via is adjacent to the second dielectric layer and wherein the via is electrically coupled with the die.
Example 43 includes the package of example 42, or of any other example or embodiment herein, wherein the via is adjacent to the first layer and adjacent to the second layer.
Example 44 includes the package of example 42, or of any other example or embodiment herein, wherein the substrate is a portion of a serializer/deserializer device.
Example 45 includes the package of example 42, or of any other example or embodiment herein, wherein the first dielectric layer and the second dielectric layer are different dielectric compounds.
Example 46 is a method comprising: providing a first dielectric layer; providing a trace on the first dielectric layer; providing a layer of silicide on the trace and on the first dielectric layer; providing a layer of silicon nitride on the layer of silicide; and providing a second dielectric layer on the layer of silicon nitride.
Example 47 includes the method of example 46, or of any other example or embodiment herein, wherein a thickness of the layer of silicide is less than 1 μm.
Example 48 includes the method of example 47, or of any other example or embodiment herein, wherein placing the layer of silicide further includes placing the layer of silicide using a selected one of: chemical vapor deposition (CVD) process or a physical vapor deposition (PVD) process.
Example 49 includes the method of example 46, or of any other example or embodiment herein, wherein placing the layer of silicon nitride further includes placing the layer of silicon nitride using a selected one of: a CVD process or a PVD process.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A substrate comprising:
a first dielectric layer;
a feature on the first dielectric layer, the feature including copper;
a first layer on at least part of the feature, the first layer comprising silicon and at least one of copper, cobalt, ruthenium, or tungsten;
a second layer on the first layer, the second layer comprising silicon and nitrogen; and
a second dielectric layer on the second layer.

2. The substrate of claim 1, wherein the feature is a selected one or more of: a pad or a trace.

3. The substrate of claim 1, wherein the first layer comprises a silicide.

4. The substrate of claim 1, wherein a thickness of the first layer is less than 1 μm.

5. The substrate of claim 1, wherein a thickness of the second layer is less than 1 μm.

6. The substrate of claim 1, wherein the at least part of the copper feature includes a portion of a top surface of the copper feature opposite the first dielectric layer.

7. The substrate of claim 1, wherein the second dielectric layer is a build up layer.

8. The substrate of claim 1, wherein the second layer does not come into direct physical contact with the feature.

9. The substrate of claim 1, wherein a portion of the first layer and a portion of the second layer of silicon nitride are on a portion of the first dielectric layer.

10. The substrate of claim 1, wherein the feature is a first feature; and further comprising:
a second feature, wherein the second feature includes copper and wherein the second feature is on the first dielectric layer;
wherein the first layer is on at least part of the second feature; and
wherein the second layer is on the second layer that is on at least part of the second feature that includes copper.

11. The substrate of claim 10, wherein a distance between the first feature and the second feature is less than 50 μm.

12. The substrate of claim 1, wherein the first feature is a trace; and further comprising a via electrically coupled to the trace.

13. The substrate of claim 1, wherein a smoothness of the surface of the feature has a roughness of less than 100 nm Ra.

14. The substrate of claim 1, wherein the first layer and the second layer adhere the second dielectric layer to the feature.

15. A package comprising:
a die; and
a substrate electrically coupled with the die, the substrate including:
a first dielectric layer;
a trace on the first dielectric layer, the trace including copper;
a first layer on at least part of the trace, the first layer comprising silicon and at least one of copper, cobalt, ruthenium, or tungsten;
a second layer on the first layer, the second layer comprising silicon and nitrogen; and
a second dielectric layer on the second layer, wherein the first layer and the second layer are between a portion of the second dielectric layer and the at least part of the trace.

16. The package of claim 15, wherein the die is electrically coupled with the trace.

17. The package of claim 16, further comprising a via that is directly electrically coupled with the trace, wherein the via includes copper and wherein the via is adjacent to the second dielectric layer and wherein the via is electrically coupled with the die.

18. The package of claim 17, wherein the via is adjacent to the first layer and adjacent to the second layer.

19. The package of claim 17, wherein the substrate is a portion of a serializer/deserializer device.

20. The package of claim 17, wherein the first dielectric layer and the second dielectric layer are different dielectric compounds.

21. A method comprising:
providing a first dielectric layer;
providing a trace on the first dielectric layer;
providing a layer of silicide on the trace and on the first dielectric layer;
providing a layer of silicon nitride on the layer of silicide; and
providing a second dielectric layer on the layer of silicon nitride.

22. The method of claim 21, wherein a thickness of the layer of silicide is less than 1 μm.

23. The method of claim 21, wherein placing the layer of silicide further includes placing the layer of silicide using a selected one of: chemical vapor deposition (CVD) process or a physical vapor deposition (PVD) process.

24. The method of claim 21, wherein placing the layer of silicon nitride further includes placing the layer of silicon nitride using a selected one of: a CVD process or a PVD process.
